(19) United States
(12) Patent Application Publication
(10) Pub. No.: US 2025/0089581 A1
(43) Pub. Date: Mar. 13, 2025

(54) RADIO FREQUENCY SWITCHING UNIT, MANUFACTURING METHOD THEREOF AND ELECTRONIC APPARATUS

(71) Applicants: Beijing BOE Technology Development Co., Ltd., Beijing (CN); BOE TECHNOLOGY GROUP CO., LTD., Beijing (CN)

(72) Inventor: Hu MENG, Beijing (CN)

(21) Appl. No.: 18/580,086

(22) PCT Filed: Aug. 17, 2022
(86) PCT No.: PCT/CN2022/113084

§ 371 Date: Jan. 17, 2024

(51) Int. Cl. H10N 70/00

(52) U.S. Cl. CPC H10N 70/8265; H10N 70/841; H10N 70/8833

(57) ABSTRACT

The present disclosure provides a radio frequency switching unit, a method for manufacturing a radio frequency switching unit and an electronic apparatus, and belongs to the field of radio frequency technology. The radio frequency switching unit of the present disclosure includes: a dielectric substrate, and a first electrode, a second electrode, a metal oxide semiconductor layer, and a barrier layer on the dielectric substrate. The metal oxide semiconductor layer and the barrier layer are both between the first electrode and the second electrode, and the barrier layer is closer to a layer where the first electrode is located than the metal oxide semiconductor layer. The metal oxide semiconductor layer is configured to electrically connect the first electrode to the second electrode through the hollowed-out pattern when an operating voltage is applied between the first electrode and the second electrode.

### TECHNICAL FIELD

The present disclosure relates to the field of radio frequency device technology, and in particular to a radio frequency switching unit, a method for manufacturing a radio frequency switching unit and an electronic apparatus.

### BACKGROUND

Currently, a radio frequency switch is widely used in the field of communication, especially in a frequency reconfigurable antenna. A frequency of the antenna is reconfigurable within a certain range by loading a control switch in the frequency reconfigurable antenna. The frequency reconfigurable antenna is characterized in that a resonant frequency of the antenna may be adjusted without increasing or reducing the number of radiating units of the antenna, so that the frequency reconfigurable antenna has the advantages of simple structure and small occupied space. In the prior art, the control switch is usually made of a silicon-based CMOS (Complementary Metal-Oxide-Semiconductor Transistor) or SOI (silicon on insulator) switch, a varactor, a liquid crystal, an MEMS (Micro-electromechanical Systems), or a phase change material, or the like, so as to realize frequency reconfiguration. The silicon-based switch or the varactor has an obvious influence on indexes (such as a gain and efficiency) of the antenna. A liquid crystal reconfigurable antenna has a long response time. An MEMS switch has advantages in insertion loss, power consumption, size, cost, and the like, but has a high driving voltage, strict requirements on materials and processes, and a great process difficulty. Phase change materials require additional thermal management materials and processes, and high temperature operation and low temperature operation are more critical to reliability.

A novel radio frequency switch based on a resistance variable principle has received extensive attention and research of people in recent years. The switch has non-volatility, and low static power consumption, and has high performances in insertion loss, isolation, response time and the like, and thus, becomes a competitive candidate for a next-generation radio frequency switch. However, a conductive ON and a conductive OFF of a resistance variable switch is realized based on random distribution of atoms and ions, so that the robustness of the switch is poor, and the problems in terms of reliability and uniformity need to be solved.

### SUMMARY

The present disclosure is directed to at least one of the technical problems of the prior art, and provides a radio frequency switching unit, a method for manufacturing a radio frequency switching unit and an electronic apparatus.

An embodiment of the present disclosure provides a radio frequency switching unit, including: a dielectric substrate, a first electrode, a second electrode, a metal oxide semiconductor layer, and a barrier layer on the dielectric substrate; the metal oxide semiconductor layer and the barrier layer are both between the first electrode and the second electrode, and the barrier layer is closer to a layer where the first electrode is located than the metal oxide semiconductor layer; and the barrier layer has a hollowed-out pattern therein; and the metal oxide semiconductor layer is configured to electrically connect the first electrode to the second electrode through the hollowed-out pattern when an operating voltage is applied between the first electrode and the second electrode.

In some embodiments, the barrier layer is closer to the first electrode than the metal oxide semiconductor layer; and an orthographic projection of the hollowed-out pattern on the dielectric substrate overlaps with orthographic projections of any two of the first electrode, the metal oxide semiconductor layer and the second electrode on the dielectric substrate.

In some embodiments, the radio frequency switching unit further includes an interlayer dielectric layer between the first electrode and the barrier layer.

In some embodiments, the first electrode and the second electrode are in the same layer, the barrier layer is on a side of the layer where the first electrode and the second electrode are located away from the dielectric substrate, and the metal oxide semiconductor layer is on a side of the barrier layer away from the dielectric substrate.

In some embodiments, the barrier layer includes at least two sub-structures spaced at intervals, and a gap between every two adjacent sub-structures defines the hollowed-out pattern; and an orthographic projection of each of the first electrode and the second electrode on the dielectric substrate overlaps with an orthographic projection of each sub-structure on the dielectric substrate.

In some embodiments, the radio frequency switching unit further includes an interlayer dielectric layer between the barrier layer and the layer where the first electrode and the second electrode are located.

In some embodiments, the barrier layer is made of graphene.

In some embodiments, the first electrode and the second electrode are made of the same material.

In some embodiments, the first electrode and the second electrode are made of different materials.

In some embodiments, the metal oxide semiconductor layer is made of indium gallium zinc oxide or hafnium oxide.

In a second aspect, an embodiment of the present disclosure provides a method for manufacturing a radio frequency switching unit, including: providing a dielectric substrate, and forming, on the dielectric substrate, a first electrode, a second electrode, a metal oxide semiconductor layer and a barrier layer between the first electrode and the second electrode; the barrier layer is closer to the layer where the first electrode is located than the metal oxide semiconductor layer; the barrier layer has a hollowed-out pattern therein; and the metal oxide semiconductor layer is configured to electrically connect the first electrode to the second electrode through the hollowed-out pattern when an operating voltage is applied between the first electrode and the second electrode.

In some embodiments, the forming the first electrode, the second electrode, the metal oxide semiconductor layer, and the barrier layer includes: forming the first electrode on the dielectric substrate; forming the barrier layer with the hollowed-out pattern on a side of the first electrode away from the dielectric substrate; forming the metal oxide semiconductor layer on a side of the barrier layer away from the first electrode; and forming the second electrode on a side of the metal oxide semiconductor away from the barrier layer; and an orthographic projection of the hollowed-out pattern on the dielectric substrate overlaps with orthographic projections of any two of the first electrode, the metal oxide semiconductor layer and the second electrode on the dielectric substrate.

In some embodiments, between the forming the first electrode on the dielectric substrate and the forming the barrier layer with the hollowed-out pattern on a side of the first electrode away from the dielectric substrate, the method further includes: forming an interlayer dielectric layer on a side of the first electrode away from the dielectric substrate.

In some embodiments, the forming the interlayer dielectric layer on a side of the first electrode away from the dielectric substrate includes: performing thermal oxidation treatment on a part of the material of the first electrode, to form the interlayer dielectric layer.

In some embodiments, the forming the first electrode, the second electrode, the metal oxide semiconductor layer, and the barrier layer includes: forming the first electrode and the second electrode on the dielectric substrate; forming the barrier layer with the hollowed-out pattern on a side of the first electrode and the second electrode away from the dielectric substrate; and forming the metal oxide semiconductor layer on a side of the barrier layer away from a layer where the first electrode and the second electrode are located.

In some embodiments, the barrier layer includes at least two sub-structures at intervals, and a gap between every two adjacent sub-structures defines the hollowed-out pattern; and an orthographic projection of each of the first electrode and the second electrode on the dielectric substrate overlaps with an orthographic projection of each sub-structure on the dielectric substrate.

In some embodiments, between the forming the first electrode and the second electrode on the dielectric substrate and the forming the barrier layer with the hollowed-out pattern on a side of the first electrode and the second electrode away from the dielectric substrate, the method further includes: forming an interlayer dielectric layer on a side of the layer where the first electrode and the second electrode are located away from the dielectric substrate.

In some embodiments, the forming the interlayer dielectric layer on a side of the first electrode away from the dielectric substrate includes: performing thermal oxidation treatment on a part of the material of the first electrode and the second electrode, to form the interlayer dielectric layer.

In some embodiments, the barrier layer is made of graphene.

In a third aspect, an embodiment of the present disclosure provides an electronic apparatus, which includes the radio frequency switching unit.

### BRIEF DESCRIPTION OF DRAWINGS

FIG. 1 is a cross-sectional view of a radio frequency switching unit in a first example of an embodiment of the present disclosure.

FIG. 2 is a flowchart of a method for manufacturing the radio frequency switching unit shown in FIG. 1.

FIG. 3 is a cross-sectional view of another radio frequency switching unit in the first example of the embodiment of the present disclosure.

FIG. 4 is a flowchart of a method for manufacturing the radio frequency switching unit shown in FIG. 3.

FIG. 5 is a top view of a radio frequency switching unit in a second example of an embodiment of the present disclosure.

FIG. 6 is a cross-sectional view taken along a line A-A′ of the radio frequency switching unit shown in FIG. 5.

FIG. 7 is a cross-sectional view taken along a line B-B′ of the radio frequency switching unit shown in FIG. 5.

FIG. 8 is a flowchart of a method for manufacturing the radio frequency switching unit shown in FIG. 5.

FIG. 9 is a schematic diagram of a first electrode and a second electrode, each having a trapezoidal shape, of the radio frequency switching unit in the second example of the embodiment of the present disclosure.

FIG. 10 is a schematic diagram of a first electrode and a second electrode, each having a triangular shape, of the radio frequency switching unit in the second example of the embodiment of the present disclosure.

FIG. 11 is a top view of another radio frequency switching unit in the second example of the embodiment of the present disclosure.

FIG. 12 is a cross-sectional view taken along a line C-C′ of the radio frequency switching unit shown in FIG. 11.

FIG. 13 is a flowchart of a method for manufacturing the radio frequency switching unit shown in FIG. 11.

### DETAIL DESCRIPTION OF EMBODIMENTS

In order to enable one of ordinary skill in the art to better understand the technical solutions of the embodiments of the present disclosure, the present invention will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

In a first aspect, an embodiment of the present disclosure provides a radio frequency switching unit, which includes a dielectric substrate, a first electrode, a second electrode, a metal oxide semiconductor layer, and a barrier layer disposed on the dielectric substrate. The metal oxide semiconductor layer and the barrier layer are both located between the first electrode and the second electrode, and the barrier layer is closer to a layer where the first electrode is located than the metal oxide semiconductor layer; and the barrier layer is provided with a hollowed-out pattern; the metal oxide semiconductor layer is configured to electrically connect the first electrode to the second electrode through the hollowed-out pattern when an operating voltage is applied between the first electrode and the second electrode. That is, when the operating voltage is applied between the first electrode and the second electrode, a conductive path is formed in the metal oxide semiconductor layer at a position corresponding to the hollowed-out pattern so as to electrically connect the first electrode to the second electrode.

In the radio frequency switching unit according to the embodiment of the present disclosure, by providing the patterned barrier layer, that is, the barrier layer having the hollowed-out pattern, when the operating voltage is applied between the first electrode and the second electrode, the conductive path is formed in the metal oxide semiconductor layer at the position corresponding to the hollowed-out pattern so as to electrically connect the first electrode to the second electrode. In this way, the discreteness of the operating voltage of the switching device is suppressed, and the radio frequency switching unit with higher uniformity and reliability is realized. The radio frequency switching unit in the embodiment of the present disclosure has the advantages of low power consumption, high phase speed and high radio frequency performance, and is suitable for low-cost large-area preparation.

Correspondingly, the embodiment of the present disclosure further provides a method for manufacturing a radio frequency switching unit, which may be used for manufacturing the radio frequency switching unit. The method for manufacturing a radio frequency switching unit includes: providing a dielectric substrate, forming, on the dielectric substrate, a first electrode, a second electrode, a metal oxide semiconductor layer and a barrier layer located between the first electrode and the second electrode; the barrier layer is closer to the layer where the first electrode is located than the metal oxide semiconductor layer; the barrier layer is provided with a hollowed-out pattern; when the operating voltage is applied between the first electrode and the second electrode, a conductive path is formed in the metal oxide semiconductor layer at a position corresponding to the hollowed-out pattern so as to electrically connect the first electrode to the second electrode.

The radio frequency switching unit and the method for manufacturing a radio frequency switching unit according to the embodiments of the present disclosure are described below with reference to specific examples.

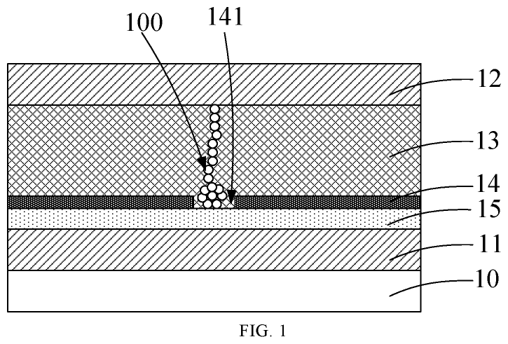

In a first example, FIG. 1 is a cross-sectional view of a radio frequency switching unit in a first example of an embodiment of the present disclosure. As shown in FIG. 1, a first electrode 11, a barrier layer 14, a metal oxide semiconductor layer 13 and a second electrode 12 of the radio frequency switching unit are sequentially stacked on the dielectric substrate 10. An orthographic projection of the hollowed-out pattern 141 on the dielectric substrate 10 overlaps with orthographic projections of any two of the first electrode 11, the metal oxide semiconductor layer 13 and the second electrode 12 on the dielectric substrate 10. In this case, when an operating voltage, for example, a forward voltage, is applied between the first electrode 11 and the second electrode 12, a conductive path is formed in the metal oxide semiconductor layer 13 at a position corresponding to the hollowed-out pattern 141, thereby electrically connecting the first electrode 11 to the second electrode 12.

In some examples, an interlayer dielectric layer 15 is arranged between layers where the first electrode 11 and the barrier layer 14 are located, so that there is a proper distance between the first electrode 11 and the barrier layer 14, and the surface of the first electrode 11 is flat.

In some examples, the first electrode 11 and the second electrode 12 may be made of the same material or different materials. For example: the first electrode 11 and the second electrode 12 are both made of Al. Alternatively, the first electrode 11 is made of silver, and the second electrode 12 is made of Cu.

In some examples, a material of the metal oxide semiconductor layer 13 includes, but is not limited to, indium gallium zinc oxide or hafnium oxide.

In some examples, a material of barrier layer 14 includes, but is not limited to, graphene.

The structure of the radio frequency switching unit in the first example is explained below with reference to specific examples.

In one example, the first electrode 11 and the second electrode 12 of the radio frequency switching unit are both made of Al, the metal oxide semiconductor layer 13 is made of indium gallium zinc oxide, the interlayer dielectric layer 15 is made of aluminum oxide, and the barrier layer 14 is made of graphene.

For such a radio frequency switching unit, when a forward voltage is applied between the first electrode 11 and the second electrode 12 for forward scanning, the current of the radio frequency switching unit slowly increases, and is steeply changed at a voltage of about 1.5V, and a resistance of the radio frequency switching unit significantly decreases, thereby forming a low resistance state. The voltage is an operating voltage. On the contrary, when the forward voltage is applied for reverse scanning, the current of the radio frequency switching unit does not change, but is steeply changed again at a voltage of 0.5V, and the resistance is obviously increased, thereby forming a high resistance state. This voltage is a reset voltage.

To explain the operating principle of the above radio frequency device, under the action of the forward voltage, a balance between oxygen vacancies and oxygen atoms occupations inside the indium gallium zinc oxide IGZO material of the metal oxide semiconductor layer 13 of the radio frequency switching unit is broken, the oxygen vacancies are gradually increased and arranged along a direction of an electric field. When the operating voltage is reached, a channel for the oxygen vacancies will connect the first electrode 11 to the second electrode 12 at a position corresponding to the hollowed-out pattern 141 of the barrier layer 14, to form the conductive path 100. The radio frequency switching unit reaches the low resistance state. On the contrary, when the voltage is changed from a large value to a small value, the number of oxygen vacancies is gradually reduced. When the reset voltage is reached, the conductive path 100 is broken and the radio frequency switching unit reaches the high resistance state. It should be noted that the barrier layer 14 for migration of oxygen atoms is formed in the honeycomb structure of graphene forming the barrier layer 14 due to the honeycomb structure, so that the conductive path 100 only appears at the position of the hollowed-out pattern 141 of the barrier layer 14 made of graphene, thereby suppressing a discrete distribution of the conductive path 100 in a two-dimensional plane. In this way, the resistance variable radio frequency switching unit is obtained with better uniformity, better repeatability and higher robustness.

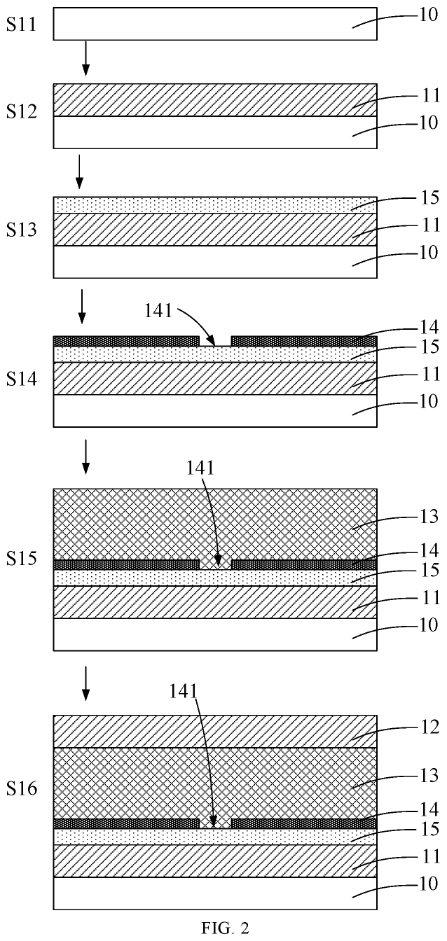

The method for manufacturing a radio frequency switching unit is described below. FIG. 2 is a flow chart of a method of manufacturing the radio frequency switching unit shown in FIG. 1. As shown in FIG. 2, the method for manufacturing a radio frequency switching unit specifically includes the following steps S11 to S16.

The step S11 includes providing a dielectric substrate 10.

In some examples, the dielectric substrate 10 may be a glass substrate. In the step S11, a 0.5T glass substrate may be selected, and then the glass substrate is cleaned through a standard cleaning process.

The step S12 includes forming a pattern including the first electrode 11 through a patterning process.

In some examples, the step S12 may be implemented in the following way. A first conductive material is formed through a process, including, but not limited to, a magnetron sputtering process. The first conductive material may be Al, and have a thickness in a range from about 100 nm to 300 nm. Then, the pattern including the first electrode 11 is formed by coating photoresist, exposing, developing, and etching (e.g., wet etching).

The step S13 includes forming an interlayer dielectric layer 15.

In some examples, a material of the interlayer dielectric layer 15 is aluminum oxide, and in the step S13, the interlayer dielectric layer 15 made of aluminum oxide may be formed by using an atomic layer deposition. Alternatively, the aluminum oxide may be formed by performing thermal oxidation treatment on a part of the material of the first electrode 11. A thickness of the aluminum oxide is in a range from 5 nm to 10 nm. It should be noted that the thickness of the aluminum oxide is relatively thin, so the arrangement of the interlayer dielectric layer 15 does not affect the switching characteristics of the radio frequency switching unit.

The step S14 includes forming a barrier layer 14 with the hollowed-out pattern 141.

In some examples, the material of the barrier layer 14 may be graphene. When the material of the barrier layer 14 may be graphene, the step S14 may include: growing a single-layer of graphene on a copper foil by chemical vapor deposition, transferring the single-layer of graphene to a side of the interlayer dielectric layer 15 away from the dielectric substrate 10 by a transfer process, and forming a pattern of a graphene layer by nano-imprinting or electron beam exposure and a dry etching process, that is, forming the barrier layer 14 with the hollowed-out pattern 141.

The step S15 includes forming a metal oxide semiconductor layer 13.

In some examples, the material of the metal oxide semiconductor layer 13 may is indium gallium zinc oxide. In the step S15, a semiconductor material layer may be formed by magnetron sputtering, and then patterned through a lift off process to form the metal oxide semiconductor layer 13. A thickness of the metal oxide semiconductor layer 13 is in a range from about 20 nm to 100 nm.

The step S16 includes forming a second electrode 12.

In some examples, the step S16 may be implemented in the following way. A second conductive material is formed through a process, including, but not limited to, a magnetron sputtering process. The second conductive material may be Al, and have a thickness in a range from about 100 nm to 300 nm. Then, the second conductive material is patterned through a lift off process to form a pattern including the second electrode 12.

Thus, the manufacturing of the radio frequency switching unit is completed.

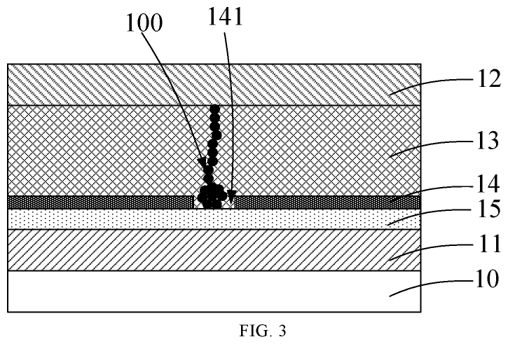

In another example, FIG. 3 is a cross-sectional view of another radio frequency switching unit in the first example of the embodiment of the present disclosure. As shown in FIG. 3, the first electrode 11 of the radio frequency switching unit is made of copper Cu, the second electrode 12 is made of silver Ag, the metal oxide semiconductor layer 13 is made of hafnium oxide HfO₂, the interlayer dielectric layer 15 is made of hafnium oxide HfO₂, and the barrier layer 14 is made of graphene.

To explain the operating principle of the above radio frequency device, under the action of the forward voltage, an electrochemical activity of the material Ag of the first electrode 11 is different from that of the material Cu of the second electrode 12, and Ag ions are gradually migrated and arranged along the direction of the electric field, and obtain electrons released by the material Cu of the second electrode 12 to form Ag atoms. When the operating voltage is reached, Ag atoms will connect the first electrode 11 to the second electrode 12, thereby forming the conductive path 100. The radio frequency switching unit reaches the low resistance state. On the contrary, when the voltage is changed from a large value to a small value, the number of Ag atoms is gradually reduced. When the reset voltage is reached, the conductive path 100 is broken and the radio frequency switching unit reaches the high resistance state. It should be noted that the barrier layer 14 for migration of oxygen atoms is formed in the honeycomb structure of graphene due to the honeycomb structure, so that the conductive path 100 only appears at the position of the hollowed-out pattern 141 of the barrier layer 14 made of graphene, thereby suppressing a discrete distribution of the conductive path 100 on a two-dimensional plane. In this way, the resistance variable radio frequency switching unit is obtained with better uniformity, better repeatability and higher robustness.

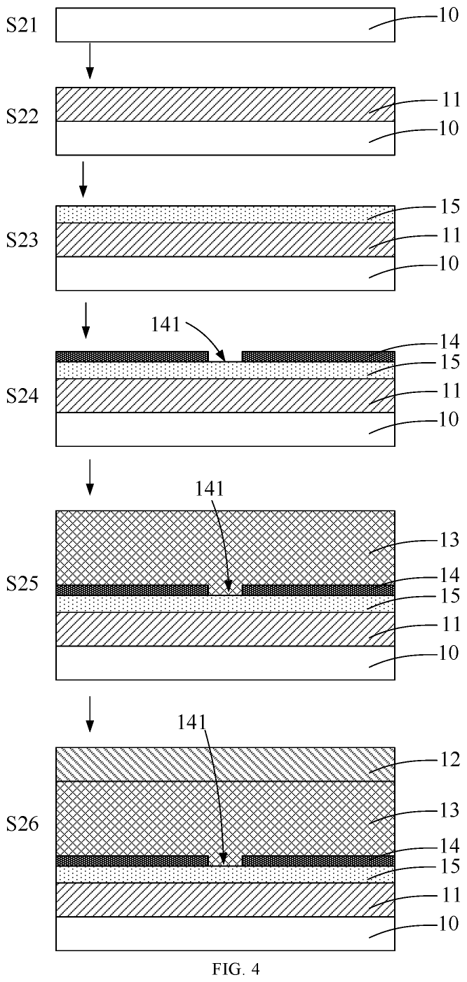

The method for manufacturing a radio frequency switching unit is described below. FIG. 4 is a flow chart of a method of manufacturing the radio frequency switching unit shown in FIG. 3. As shown in FIG. 4, the method for manufacturing a radio frequency switching unit specifically includes the following steps S21 to S26.

The step S21 includes providing a dielectric substrate 10.

In some examples, the dielectric substrate 10 may be a glass substrate. In the step S21, a 0.5T glass substrate may be selected, and then the glass substrate is cleaned through a standard cleaning process.

The step S22 includes forming a pattern including the first electrode 11 through a patterning process.

In some examples, the step S22 may be implemented in the following way. A first conductive material is formed through a process, including, but not limited to, a magnetron sputtering process. The first conductive material may be Cu, and have a thickness in a range from about 100 nm to 300 nm. Then, the pattern including the first electrode 11 is formed by coating photoresist, exposing, developing, and etching (e.g., wet etching).

The step S23 includes forming an interlayer dielectric layer 15.

In some examples, a material of the interlayer dielectric layer 15 is hafnium oxide, and in the step S23, the interlayer dielectric layer 15 made of hafnium oxide may be formed by using an atomic layer deposition. Alternatively, the hafnium oxide may be formed by performing thermal oxidation treatment on the metal hafnium. A thickness of the hafnium oxide is in a range from 5 nm to 10 nm. It should be noted that the thickness of the hafnium oxide is relatively thin, so the arrangement of the interlayer dielectric layer 15 does not affect the switching characteristics of the radio frequency switching unit.

The step S24 includes forming a barrier layer 14 with the hollowed-out pattern 141.

In some examples, the material of the barrier layer 14 may be graphene. When the material of the barrier layer 14 may be graphene, the step S24 may include: growing a single-layer of graphene on a copper foil by chemical vapor deposition, transferring the single-layer of graphene to a side of the interlayer dielectric layer 15 away from the dielectric substrate 10 through a transfer process, and forming a pattern of a graphene layer by nano-imprinting or electron beam exposure and a dry etching process, that is, forming the barrier layer 14 with the hollowed-out pattern 141.

The step S25 includes forming a metal oxide semiconductor layer 13.

In some examples, the material of the metal oxide semiconductor layer 13 may is hafnium oxide. In the step S25, a semiconductor material layer may be formed by magnetron sputtering, and then patterned through a lift off process to form the metal oxide semiconductor layer 13. A thickness of the metal oxide semiconductor layer 13 is in a range from about 20 nm to 100 nm.

The step S26 includes forming a second electrode 12.

In some examples, the step S26 may be implemented in the following way. A second conductive material is formed through a process, including, but not limited to, a magnetron sputtering process. The second conductive material may be Ag, and have a thickness in a range from about 100 nm to 300 nm. Then, the second conductive material is patterned through a lift off process to form a pattern including the second electrode 12.

Thus, the manufacturing of the radio frequency switching unit is completed.

Another specific example of the radio frequency switching unit has been given in the first example, the first electrode 11, the second electrode 12, the metal oxide semiconductor layer 13, the interlayer dielectric layer 15, and the barrier layer 14 of the above exemplary radio frequency switching unit are distributed perpendicularly to the dielectric substrate 10. It should be noted that the materials of the radio frequency switching unit given above are only some exemplary illustrations, and do not limit the scope of the embodiments of the present disclosure.

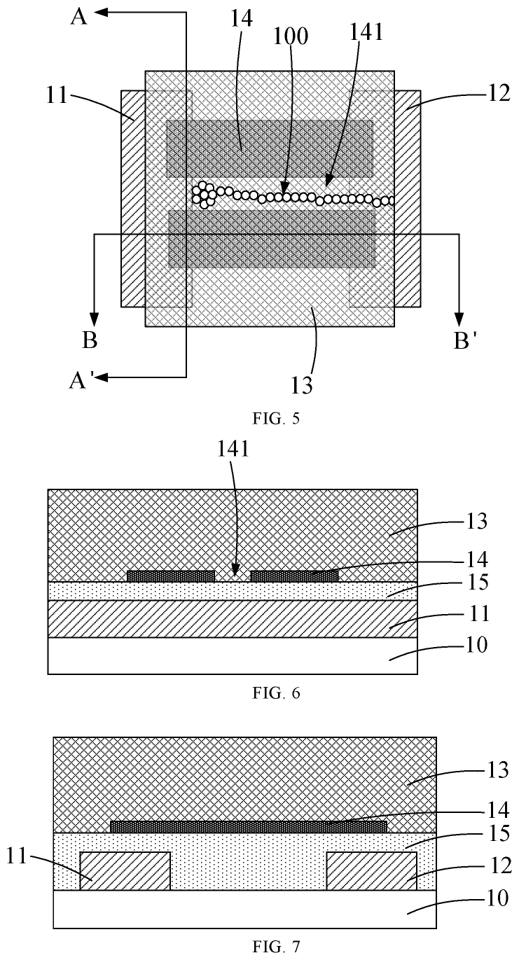

In a second example, FIG. 5 is a top view of a radio frequency switching unit in a second example of an embodiment of the present disclosure. FIG. 6 is a cross-sectional view taken along a line A-A′ of the radio frequency switching unit shown in FIG. 5. FIG. 7 is a cross-sectional view taken along a line B-B′ of the radio frequency switching unit shown in FIG. 5. As shown in FIGS. 5 to 7, the first electrode 11 and the second electrode 12 of the radio frequency switching unit are disposed in the same layer, and the barrier layer 14 and the metal oxide semiconductor layer 13 are sequentially disposed on a side of the layer where the first electrode 11 and the second electrode 12 are located, away from the dielectric substrate 10. An orthographic projection of the metal oxide semiconductor layer 13 on the dielectric substrate 10 covers a gap between the first electrode 11 and the second electrode 12, and overlaps with orthographic projections of the first electrode 11 and the second electrode 12 on the dielectric substrate 10. The hollowed-out pattern 141 of the barrier layer 14 extends through the gap between the first electrode 11 and the second electrode 12.

The operating principle of the radio frequency switching unit is the same as that in the first example, except that when the operating voltage, for example, the forward voltage, is applied between the first electrode 11 and the second electrode 12, the conductive path extending in a horizontal direction with respect to the dielectric substrate 10 is formed in the metal oxide semiconductor layer 13 at a position corresponding to the hollowed-out pattern 141, thereby electrically connecting the first electrode 11 to the second electrode 12.

In some examples, the interlayer dielectric layer 15 is disposed between layers where the first electrode 11 and the barrier layer 14 are located, so that there is a proper distance between the first electrode 11 and the barrier layer 14, and the surface of the first electrode 11 is flat.

Further, the barrier layer 14 includes a plurality of sub-structures disposed at intervals, and a gap between every two adjacent sub-structures defines the hollowed-out pattern 141 of the barrier layer 14.

In some examples, the first electrode 11 and the second electrode 12 may be the same material or different materials. For example: the first electrode 11 and the second electrode 12 are both made of Al. Alternatively, the first electrode 11 is made of silver, and the second electrode 12 is made of Cu. The patterns of the first electrode 11 and the second electrode 12 may be rectangular, triangular, or trapezoidal, or the like.

In some examples, the material of the metal oxide semiconductor layer 13 includes, but is not limited to, indium gallium zinc oxide or hafnium oxide.

In some examples, the material of the barrier layer 14 includes, but is not limited to, graphene.

The structure of the radio frequency switching unit in the second example is explained below with reference to a specific example.

In one example, the first electrode 11 and the second electrode 12 of the radio frequency switching unit are made of Al, the metal oxide semiconductor layer 13 is made of indium gallium zinc oxide, the interlayer dielectric layer 15 is made of aluminum oxide, and the barrier layer 14 is made of graphene.

To explain the operating principle of the above radio frequency device, under the action of the forward voltage, a balance between oxygen vacancies and oxygen atoms occupations inside the indium gallium zinc oxide IGZO material of the metal oxide semiconductor layer 13 of the radio frequency switching unit is broken, the oxygen vacancies are gradually increased and arranged along a direction of an electric field. When the operating voltage is reached, a channel for the oxygen vacancies will connect the first electrode 11 to the second electrode 12 at a position corresponding to the hollowed-out pattern 141 of the barrier layer 14, to form the conductive path 100. The radio frequency switching unit reaches the low resistance state. On the contrary, when the voltage is changed from a large value to a small value, the number of oxygen vacancies is gradually reduced. When the reset voltage is reached, the conductive path 100 is broken and the radio frequency switching unit reaches the high resistance state. It should be noted that the barrier layer 14 for migration of oxygen atoms is formed in the honeycomb structure of graphene forming the barrier layer 14 due to the honeycomb structure, so that the conductive path 100 only appears at the position of the hollowed-out pattern 141 of the barrier layer 14 made of graphene, thereby suppressing a discrete distribution of the conductive path 100 on a two-dimensional plane. In this way, the resistance variable radio frequency switching unit is obtained with better uniformity, better repeatability and higher robustness.

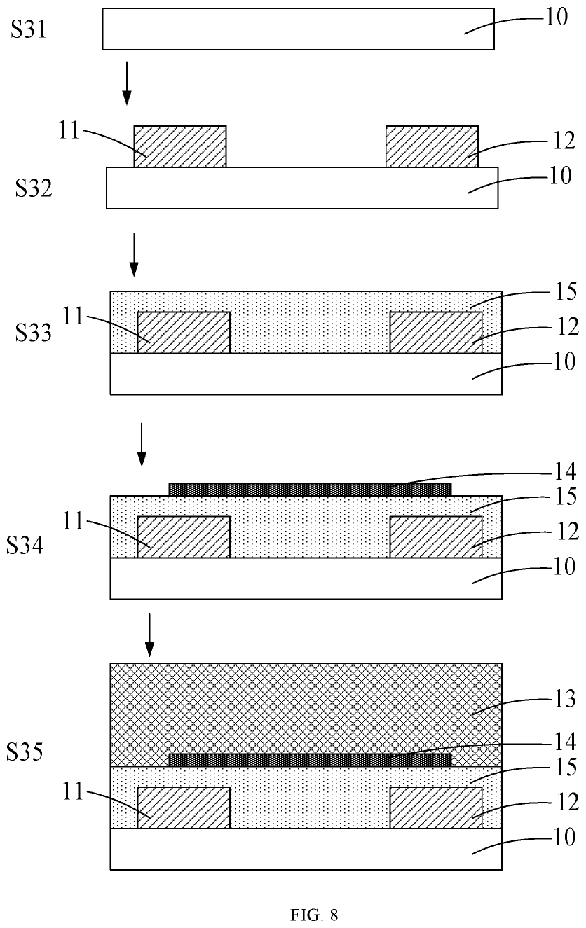

The method for manufacturing a radio frequency switching unit is described below. FIG. 8 is a flow chart of a method of manufacturing the radio frequency switching unit shown in FIG. 5. As shown in FIG. 8, the method for manufacturing a radio frequency switching unit specifically includes the following steps S31 to S35.

The step S31 includes providing a dielectric substrate 10.

In some examples, the dielectric substrate 10 may be a glass substrate. In the step S31, a 0.5T glass substrate may be selected, and then the glass substrate is cleaned through a standard cleaning process.

The step S32 includes forming a pattern including the first electrode 11 and the second electrode 12 through a patterning process.

In some examples, the step S32 may be implemented in the following way. A first conductive material is formed through a process, including, but not limited to, a magnetron sputtering process. The first conductive material may be Al, and have a thickness in a range from about 100 nm to 300 nm. Then, the pattern including the first electrode 11 and the second electrode 12 is formed by coating photoresist, exposing, developing, and etching (e.g., wet etching). The gap between the first electrode 11 and the second electrode 12 is in a range from about 20 nm to 100 nm.

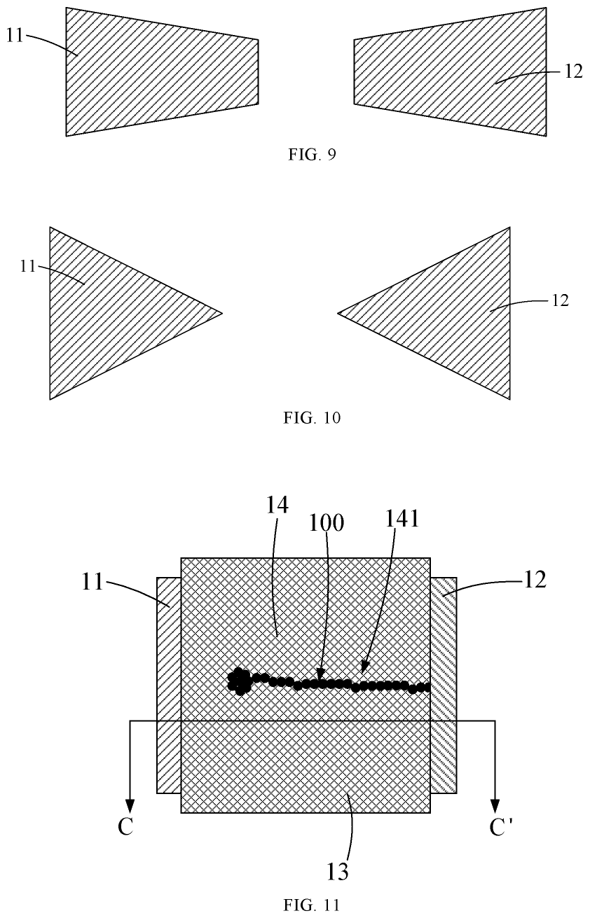

Further, FIG. 9 is a schematic diagram of a first electrode 11 and a second electrode 12 having a trapezoidal shape of the radio frequency switching unit in the second example of the embodiment of the present disclosure. FIG. 10 is a schematic diagram of a first electrode 11 and a second electrode 12 having a triangular shape of the radio frequency switching unit in the second example of the embodiment of the present disclosure. The first electrode 11 and the second electrode 12 have the same pattern and are symmetrically disposed. For example: the first electrode 11 and the second electrode 12 are both rectangular, or both trapezoidal as shown in FIG. 9; or both triangular as shown in FIG. 10.

The step S33 includes forming an interlayer dielectric layer 15.

In some examples, a material of the interlayer dielectric layer 15 is aluminum oxide, and in the step S33, the interlayer dielectric layer 15 made of aluminum oxide may be formed by using an atomic layer deposition. Alternatively, the aluminum oxide may be formed by performing thermal oxidation treatment on a part of the material of the first electrode 11 and the second electrode 12. A thickness of the aluminum oxide is in a range from 5 nm to 10 nm. It should be noted that the thickness of the aluminum oxide is relatively thin, so the arrangement of the interlayer dielectric layer 15 does not affect the switching characteristics of the radio frequency switching unit.

The step S34 includes forming a barrier layer 14 with the hollowed-out pattern 141.

In some examples, the material of the barrier layer 14 may be graphene. When the material of the barrier layer 14 may be graphene, the step S34 may include: growing a single-layer of graphene on a copper foil by chemical vapor deposition, transferring the single-layer of graphene to a side of the interlayer dielectric layer 15 away from the dielectric substrate 10 by a transfer process, and forming a pattern of a graphene layer by nano-imprinting or electron beam exposure, and a dry etching process, that is, forming the barrier layer 14 with the hollowed-out pattern 141.

The step S35 includes forming a metal oxide semiconductor layer 13.

In some examples, the material of the metal oxide semiconductor layer 13 may is indium gallium zinc oxide. In the step S35, a semiconductor material layer may be formed by magnetron sputtering, and then patterned through a lift off process to form the metal oxide semiconductor layer 13. A thickness of the metal oxide semiconductor layer 13 is in a range from about 20 nm to 100 nm.

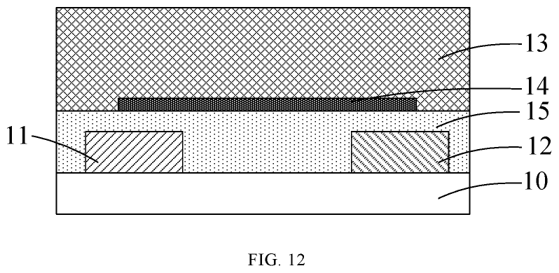

In another example, FIG. 11 is a top view of another radio frequency switching unit in the second example of the embodiment of the present disclosure. FIG. 12 is a cross-sectional view taken along a line C-C′ of the radio frequency switching unit shown in FIG. 11. As shown in FIGS. 11 and 12, the first electrode 11 of the radio frequency switching unit is made of copper Cu, the second electrode 12 is made of silver Ag, the metal oxide semiconductor layer 13 is made of hafnium oxide HfO₂, the interlayer dielectric layer 15 is made of hafnium oxide HfO₂, and the barrier layer 14 is made of graphene.

To explain the operating principle of the above radio frequency device, under the action of the forward voltage, an electrochemical activity of the material Ag of the first electrode 11 is different from that of the material Cu of the second electrode 12, and Ag ions are gradually migrated and arranged along the direction of the electric field, and obtain electrons released by the material Cu of the second electrode 12 to form Ag atoms. When the operating voltage is reached, Ag atoms will connect the first electrode 11 to the second electrode 12, thereby forming the conductive path 100. The radio frequency switching unit reaches the low resistance state. On the contrary, when the voltage is changed from a large value to a small value, the number of Ag atoms is gradually reduced. When the reset voltage is reached, the conductive path 100 is broken and the radio frequency switching unit reaches the high resistance state. It should be noted that the barrier layer 14 for migration of oxygen atoms is formed in the honeycomb structure of graphene due to the honeycomb structure, so that the conductive path 100 only appears at the position of the hollowed-out pattern 141 of the barrier layer 14 made of graphene, thereby suppressing a discrete distribution of the conductive path 100 on a two-dimensional plane. In this way, the resistance variable radio frequency switching unit is obtained with better uniformity, better repeatability and higher robustness.

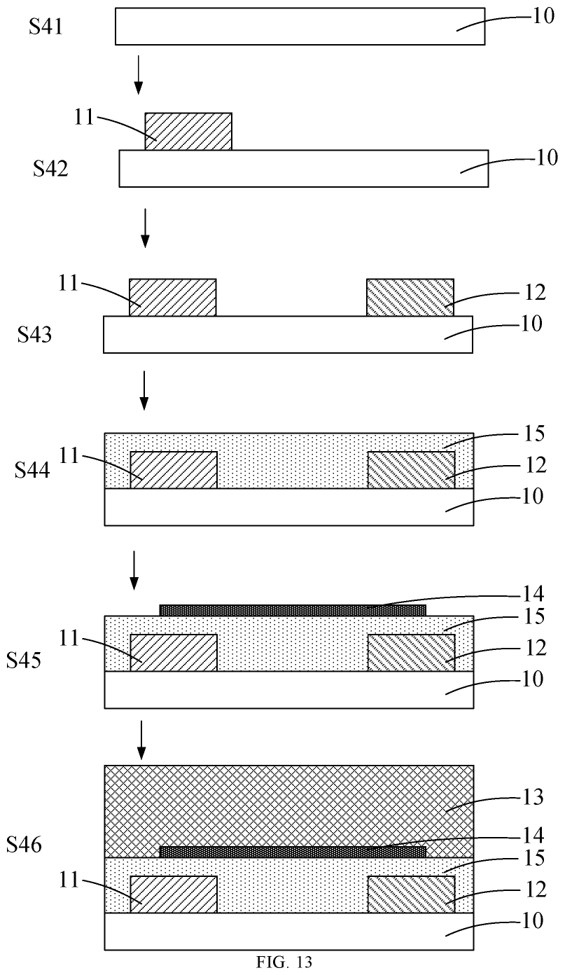

The method for manufacturing a radio frequency switching unit is described below. FIG. 13 is a flow chart of a method of manufacturing the radio frequency switching unit shown in FIG. 11. As shown in FIG. 13, the method for manufacturing a radio frequency switching unit specifically includes the following steps S41 to S46.

The step S41 includes providing a dielectric substrate 10.

In some examples, the dielectric substrate 10 may be a glass substrate. In the step S41, a 0.5T glass substrate may be selected, and then the glass substrate is cleaned through a standard cleaning process.

The step S42 includes forming a pattern including the first electrode 11 through a patterning process.

In some examples, the step S42 may be implemented in the following way. A first conductive material is formed through a process, including, but not limited to, a magnetron sputtering process. The first conductive material may be Cu, and have a thickness in a range from about 100 nm to 300 nm. Then, the pattern including the first electrode 11 is formed by coating photoresist, exposing, developing, and etching (e.g., wet etching).

The step S43 includes forming a pattern including the second electrode 12 through a patterning process.

In some examples, the step S43 may be implemented in the following way. A second conductive material is formed through a process, including, but not limited to, a magnetron sputtering process. The second conductive material may be Ag, and have a thickness in a range from about 100 nm to 300 nm. Then, the second conductive material is patterned through a lift off process to form the pattern including the second electrode 12. A width of the second electrode 12 is in a range from about 3 μm to 10 μm.

The step S44 includes forming an interlayer dielectric layer 15.

In some examples, a material of the interlayer dielectric layer 15 is hafnium oxide, and in the step S44, the interlayer dielectric layer 15 made of hafnium oxide may be formed by using an atomic layer deposition. Alternatively, the hafnium oxide may be formed by performing thermal oxidation treatment on the metal hafnium. A thickness of the hafnium oxide is in a range from 5 nm to 10 nm. It should be noted that the thickness of the hafnium oxide is relatively thin, so the arrangement of the interlayer dielectric layer 15 does not affect the switching characteristics of the radio frequency switching unit.

The step S45 includes forming a barrier layer 14 with the hollowed-out pattern 141.

In some examples, the material of the barrier layer 14 may be graphene. When the material of the barrier layer 14 may be graphene, the step S45 may include: growing a single-layer of graphene on a copper foil by chemical vapor deposition, transferring the single-layer of graphene to a side of the interlayer dielectric layer 15 away from the dielectric substrate 10 by a transfer process, and forming a pattern of a graphene layer by nano-imprinting or electron beam exposure and a dry etching process, that is, forming the barrier layer 14 with the hollowed-out pattern 141.

The step S46 includes forming a metal oxide semiconductor layer 13.

In some examples, the material of the metal oxide semiconductor layer 13 may is hafnium oxide. In the step S46, a semiconductor material layer may be formed by magnetron sputtering, and then patterned through a lift off process to form the metal oxide semiconductor layer 13. A thickness of the metal oxide semiconductor layer 13 is in a range from about 20 nm to 100 nm.

Thus, the manufacturing of the radio frequency switching unit is completed.

In a second aspect, the embodiment of the present disclosure provides an antenna, including the radio frequency switching unit. The antenna may further include a first radiation portion and a second radiation portion connected to each other through the radio frequency switching unit. The first radiation portion and the second radiation portion are turned on by controlling the operation of the radio frequency switching unit, so that the reconfiguration of the antenna is realized.

In a third aspect, an embodiment of the present disclosure provides an electronic apparatus which includes the antenna.

The electronic apparatus provided by an embodiment of the present disclosure further includes a transceiver unit, a radio frequency transceiver, a signal amplifier, a power amplifier, and a filtering unit. The antenna in the electronic apparatus may be used as a transmitting antenna or a receiving antenna. The transceiver unit may include a baseband and a receiving terminal, where the baseband provides a signal in at least one frequency band, such as 2G signal, 3G signal, 4G signal, 5G signal, or the like; and transmits the signal in the at least one frequency band to the radio frequency transceiver. After the signal is received by the antenna in the electronic apparatus and is processed by the filtering unit, the power amplifier, the signal amplifier and the radio frequency transceiver, the antenna may transmit the signal to the receiving terminal (such as an intelligent gateway or the like) in the transceiver unit.

Further, the radio frequency transceiver is connected to the transceiver unit and is configured to modulate the signals transmitted by the transceiver unit or demodulate the signals received by the antenna and then transmit the signals to the transceiver unit. Specifically, the radio frequency transceiver may include a transmitting circuit, a receiving circuit, a modulating circuit, and a demodulating circuit. After the transmitting circuit receives multiple types of signals provided by the baseband, the modulating circuit may modulate the multiple types of signals provided by the baseband, and then transmit the modulated signals to the antenna. The signals received by the antenna are transmitted to the receiving circuit of the radio frequency transceiver, and transmitted by the receiving circuit to the demodulating circuit, and demodulated by the demodulating circuit and then transmitted to the receiving terminal.

Further, the radio frequency transceiver is connected to the signal amplifier and the power amplifier, which are in turn connected to the filtering unit connected to at least one antenna. In the process of transmitting signals by the electronic apparatus, the signal amplifier is used for improving a signal-to-noise ratio of the signals output by the radio frequency transceiver and then transmitting the signals to the filtering unit; the power amplifier is used for amplifying the power of the signals output by the radio frequency transceiver and then transmitting the signals to the filtering unit; the filtering unit specifically includes a duplexer and a filtering circuit, the filtering unit combines signals output by the signal amplifier and the power amplifier and filters noise waves and then transmits the signals to the antenna, and the antenna radiates the signals. In the process of receiving signals by the electronic apparatus, the signals received by the antenna are transmitted to the filtering unit, which filters noise waves in the signals received by the antenna and then transmits the signals to the signal amplifier and the power amplifier, and the signal amplifier gains the signals received by the antenna to increase the signal-to-noise ratio of the signals; the power amplifier amplifies the power of the signals received by the antenna. The signals received by the antenna are processed by the power amplifier and the signal amplifier and then transmitted to the radio frequency transceiver, and the radio frequency transceiver transmits the signals to the transceiver unit.

In some embodiments, the signal amplifier may include various types of signal amplifiers, such as a low noise amplifier, without limitation.

In some embodiments, the electronic apparatus provided by the embodiments of the present disclosure further includes a power management unit connected to the power amplifier and for providing the power amplifier with a voltage for amplifying the signal.

It should be understood that, the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A radio frequency switching unit, comprising: a dielectric substrate, and a first electrode, a second electrode, a metal oxide semiconductor layer, and a barrier layer on the dielectric substrate;
wherein the metal oxide semiconductor layer and the barrier layer are both between the first electrode and the second electrode, and the barrier layer is closer to a layer where the first electrode is located than the metal oxide semiconductor layer; wherein the barrier layer has a hollowed-out pattern therein; and
the metal oxide semiconductor layer is configured to electrically connect the first electrode to the second electrode through the hollowed-out pattern when an operating voltage is applied between the first electrode and the second electrode.

2. The radio frequency switching unit of claim 1, wherein the barrier layer is closer to the first electrode than the metal oxide semiconductor layer; and
an orthographic projection of the hollowed-out pattern on the dielectric substrate overlaps with orthographic projections of any two of the first electrode, the metal oxide semiconductor layer, and the second electrode on the dielectric substrate.

3. The radio frequency switching unit of claim 2, further comprising an interlayer dielectric layer between the first electrode and the barrier layer.

4. The radio frequency switching unit of claim 1, wherein the first electrode and the second electrode are in a same layer, the barrier layer is on a side of the layer where the first electrode and the second electrode are located away from the dielectric substrate, and the metal oxide semiconductor layer is on a side of the barrier layer away from the dielectric substrate.

5. The radio frequency switching unit of claim 4, wherein the barrier layer comprises at least two sub-structures spaced apart from each other, and a gap between every two adjacent sub-structures defines the hollowed-out pattern; and an orthographic projection of each of the first electrode and the second electrode on the dielectric substrate overlaps with an orthographic projection of each of the at least two sub-structures on the dielectric substrate.

6. The radio frequency switching unit of claim 4, further comprising an interlayer dielectric layer between the barrier layer and the layer where the first electrode and the second electrode are located.

7. The radio frequency switching unit of claim 1, wherein the barrier layer is made of graphene.

8. The radio frequency switching unit of claim 1, wherein the first electrode and the second electrode are made of a same material.

9. The radio frequency switching unit of claim 1, wherein the first electrode and the second electrode are made of different materials.

10. The radio frequency switching unit of claim 1, wherein the metal oxide semiconductor layer is made of indium gallium zinc oxide or hafnium oxide.

11. A method for manufacturing a radio frequency switching unit, comprising:
providing a dielectric substrate, and forming, on the dielectric substrate, a first electrode, a second electrode, and a metal oxide semiconductor layer and a barrier layer between the first electrode and the second electrode; wherein the barrier layer is closer to a layer where the first electrode is located than the metal oxide semiconductor layer, and the barrier layer has a hollowed-out pattern therein; wherein
the metal oxide semiconductor layer is configured to electrically connect the first electrode to the second electrode through the hollowed-out pattern when an operating voltage is applied between the first electrode and the second electrode.

12. The method of claim 11, wherein the forming the first electrode, the second electrode, the metal oxide semiconductor layer, and the barrier layer comprises:
forming the first electrode on the dielectric substrate;
forming the barrier layer with the hollowed-out pattern on a side of the first electrode away from the dielectric substrate;
forming the metal oxide semiconductor layer on a side of the barrier layer away from the first electrode; and
forming the second electrode on a side of the metal oxide semiconductor layer away from the barrier layer; wherein an orthographic projection of the hollowed-out pattern on the dielectric substrate overlaps with orthographic projections of any two of the first electrode, the metal oxide semiconductor layer and the second electrode on the dielectric substrate.

13. The method of claim 12, wherein between the forming the first electrode on the dielectric substrate and the forming the barrier layer with the hollowed-out pattern on the side of the first electrode away from the dielectric substrate, the method further comprises:
forming an interlayer dielectric layer on a side of the first electrode away from the dielectric substrate.

14. The method of claim 13, wherein the forming the interlayer dielectric layer on the side of the first electrode away from the dielectric substrate comprises:
performing a thermal oxidation treatment on a part of a material of the first electrode to form the interlayer dielectric layer.

15. The method of claim 11, wherein the forming the first electrode, the second electrode, the metal oxide semiconductor layer, and the barrier layer comprises:
forming the first electrode and the second electrode on the dielectric substrate;
forming the barrier layer with the hollowed-out pattern on a side of the first electrode and the second electrode away from the dielectric substrate; and
forming the metal oxide semiconductor layer on a side of the barrier layer away from a layer where the first electrode and the second electrode are located.

16. The method of claim 15, wherein the barrier layer comprises at least two sub-structures spaced apart from each other, and a gap between every two adjacent sub-structures defines the hollowed-out pattern; and an orthographic projection of each of the first electrode and the second electrode on the dielectric substrate overlaps with an orthographic projection of each of the at least two sub-structures on the dielectric substrate.

17. The method of claim 15, wherein between the forming the first electrode and the second electrode on the dielectric substrate and the forming the barrier layer with the hollowed-out pattern on the side of the first electrode and the second electrode away from the dielectric substrate, the method further comprises:
forming an interlayer dielectric layer on a side of a layer where the first electrode and the second electrode are located away from the dielectric substrate.

18. The method of claim 17, wherein the forming the interlayer dielectric layer on the side of the first electrode and the second electrode away from the dielectric substrate comprises:
performing a thermal oxidation treatment on a part of a material of the first electrode and the second electrode to form the interlayer dielectric layer.

19. The method of claim 11, wherein the barrier layer is made of graphene.

20. An electronic apparatus, comprising the radio frequency switching unit of claim 1.
